(19) United States
(12) Patent Application Publication
(10) Pub. No.: US 2025/0016255 A1
(43) Pub. Date: Jan. 9, 2025

(54) DISPLAY DEVICE

(71) Applicant: Samsung Display Co., Ltd., Yongin-Si (KR)

(72) Inventors: JAE-SOO JANG, Yongin-si (KR); JUYEOP SEONG, Yongin-si (KR); Jonghyuck KIM, Yongin-si (KR); HEE-KWON LEE, Yongin-si (KR); JAEWON JEONG, Yongin-si (KR)

(21) Appl. No.: 18/626,322

(22) Filed: Apr. 4, 2024

(30) Foreign Application Priority Data
Jul. 4, 2023 (KR) 10-2023-0086575

(51) Int. Cl. H04M 1/02

(52) U.S. Cl. CPC H04M 1/0222

(57) ABSTRACT

A display device is disclosed that includes a display panel, a plurality of support bars, and first and second guide members. The display panel includes a folding area and a non-folding area adjacent to the folding area. The plurality of support bars are arranged spaced apart from each other at a predetermined distance along a second direction in the folding area, extending in a first direction intersecting the second direction, and including a first surface facing the display panel and a second surface opposite to the first surface. The first and second guide members are respectively disposed at first and second ends of each of the support bars and spaced apart in the first direction. Each of the first and second guide members supports at least one of the first surface and the second surface of each of the support bars.

This U.S. non-provisional patent application claims priority under 35 U.S.C. § 119 of Korean Patent Application No. 10-2023-0086575, filed on Jul. 4, 2023, the contents of which are hereby incorporated by reference in its entirety.

### BACKGROUND

### 1. Field of Disclosure

The present disclosure relates to a display device. More particularly, the present disclosure relates to a display device capable of preventing a display panel from being damaged.

### 2. Description of the Related Art

A display device is applied to various multimedia devices, such as a television, a mobile phone, a tablet computer, a game unit, etc., to provide a user with image information. In recent years, a flexible display device that is foldable or bendable is being developed.

### SUMMARY

The present disclosure may provide a display device capable of preventing a display panel from being damaged when folded or unfolded.

The present disclosure may provide a display device capable of preventing a force from being concentrated on a certain area of a display panel when folded or unfolded.

The present disclosure may provide a display device capable of preventing a display panel from being deformed due to a force concentrated on a certain area of the display panel when folded or unfolded.

The present disclosure may provide a display device capable of preventing a display panel from being deformed in a certain area when folded or unfolded to improve a lifespan thereof.

The present disclosure may provide a display device including a support bar supporting a display panel with a constant strength when folded or unfolded.

An embodiment of a display device includes a display panel including a folding area and a non-folding area adjacent to the folding area, a plurality of support bars arranged spaced apart from each other at a predetermined distance along a one direction in the folding area, extending in a cross direction intersecting the one direction, and including a first surface facing the display panel and a second surface opposite to the first surface, and first and second guide members respectively disposed at a first end and a second end of each of the support bars and spaced apart in the cross direction. Each of the first and second guide members supports at least one of the first surface and the second surface of each of the support bars.

Each of the first and second guide members may include a first portion that does not overlap the support bars when viewed in a plane, and a second portion bent from the first portion and overlapping the support bars when viewed in the plane.

The second portion may include a first support portion extending in the cross direction and facing the first surface and a second support portion facing the second surface.

In an embodiment, the first support portion does not overlap the display panel when viewed in the plane.

The display device may further include a first plate disposed in the display panel and overlapping the folding area. The first plate includes a plurality of first support portions each having a first width in the one direction and arranged in the one direction and a plurality of second support portions each having a second width equal to or smaller than the first width in the one direction and disposed between the first support portions, and the support bars overlap the first support portions, respectively, when viewed in a plane.

The display device may further include a second plate that is disposed in the display panel, overlaps the non-folding area, and does not overlap the folding area.

In an embodiment, each of the second support portions is provided with a plurality of openings defined therethrough, and the openings are arranged in a lattice form when viewed in the plane.

In an embodiment, a first length in the cross direction of the first plate is smaller than a second length in the cross direction of the support bars.

The first and second guide members may extend in the one direction.

Each of the support bars may include a plurality of third surfaces each connecting the first surface and the second surface and facing each other in the cross direction, and the first and second guide members are in contact with the third surfaces of the support bars.

An embodiment of a display device includes a display panel including a folding area and a non-folding area adjacent to the folding area, a support plate disposed on a rear surface of the display panel and supporting the display panel, a plurality of support bars arranged spaced apart from each other at a predetermined distance along a one direction in the folding area, extending in a cross direction intersecting the one direction, and including a first surface facing the display panel and a second surface opposite to the first surface, and first and second guide members respectively disposed at a first end and a second end of each of the support bars and side spaced apart in the cross direction. Each of the first and second guide members supports at least one of the first surface and the second surface of each of the support bars.

Each of the first and second guide members may include a first portion that does not overlap the support bars when viewed in a plane and a second portion extending from the first portion to the one direction and being in contact with at least one of the first surface and the second surface.

The support plate may include a first plate overlapping the folding area. The first plate includes a plurality of first support portions each having a first width in the one direction and arranged in the one direction and a plurality of second support portions each having a second width equal to or smaller than the first width in the one direction and disposed between the first support portions, and the support bars overlap the first support portions, respectively, when viewed in a plane.

In an embodiment, each of the second support portions is provided with a plurality of openings defined therethrough, and the openings are arranged in a lattice form when viewed in the plane.

The support plate may include a second plate that overlaps the non-folding area and does not overlap the folding area.

An embodiment a display device includes a display panel including a folding area and a non-folding area adjacent to the folding area, a first plate disposed on a rear surface of the display panel and supporting the display panel in the folding area, a plurality of support bars arranged spaced apart from each other at a predetermined distance along a one direction in the folding area, extending in a cross direction intersecting the one direction, and the plurality of support bars supporting the first plate, and first and second guide members respectively supporting the support bars. The first plate includes a plurality of first support portions each having a first width in the one direction and arranged in the one direction and a plurality of second support portions each having a second width equal to or smaller than the first width in the one direction and disposed between the first support portions, and the support bars overlap the first support portions, respectively, when viewed in a plane.

Each of the support bars may include a first surface facing the rear surface of the display panel, a second surface opposite to the first surface, and a plurality of third surfaces each connecting the first surface and the second surface and facing each other in the cross direction, and each of the first and second guide members supports at least one surface of the first surface and the second surface.

Each of the first and second guide members may include a first portion that does not overlap the support bars when viewed in the plane and a second portion extending from the first portion to the one direction and being in contact with at least one of the first surface and the second surface.

In an embodiment, each of the second support portions is provided with a plurality of openings defined therethrough, and the openings are arranged in a lattice form when viewed in the plane.

The display device may further include a second plate disposed on the rear surface of the display panel and supporting the display panel in the non-folding area.

According to the above, the force is prevented from being concentrated on the certain area of a display panel when the display device is folded or unfolded, and thus, the display panel is prevented from being deformed.

According to the above, the force is prevented from being concentrated on the certain area of a display panel when the display device is folded or unfolded, and thus, the lifespan of the display device is improved.

According to the above, the support bar supports the display panel with the constant strength when the display device is folded or unfolded.

### BRIEF DESCRIPTION OF THE DRAWINGS

The above and other advantages of the present disclosure will become readily apparent by reference to the following detailed description when considered in conjunction with the accompanying drawings wherein:

FIG. 1A is an assembled perspective view of a display device in an unfolded state according to an embodiment of the present disclosure;

FIG. 1B is an assembled perspective view of a display device being inwardly folded according to an embodiment of the present disclosure;

FIG. 1C is an assembled perspective view of a display device being outwardly folded according to an embodiment of the present disclosure;

FIG. 2A is an assembled perspective view of a display device in an unfolded state according to an embodiment of the present disclosure;

FIG. 2B is an assembled perspective view of a display device being inwardly folded according to an embodiment of the present disclosure;

FIG. 3 is an exploded perspective view of a display device according to an embodiment of the present disclosure;

FIG. 4 is an exploded perspective view of a display device according to an embodiment of the present disclosure;

FIG. 5A is a cross-sectional view of a portion of a display device according to an embodiment of the present disclosure;

FIG. 5B is a cross-sectional view of a portion of a display device according to an embodiment of the present disclosure;

FIG. 5C is a plan view of a portion of a display device according to an embodiment of the present disclosure;

FIG. 5D is a cross-sectional view of a portion of a display device according to an embodiment of the present disclosure;

FIGS. 6A and 6B are cross-sectional views of display devices according to embodiments of the present disclosure;

FIG. 7 is an exploded perspective view of a display device according to an embodiment of the present disclosure; and

FIGS. 8A and 8B are cross-sectional views of a portion of a display device according to embodiments of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include”, “comprise”, and “have” (as well as their variations such as “including”), when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

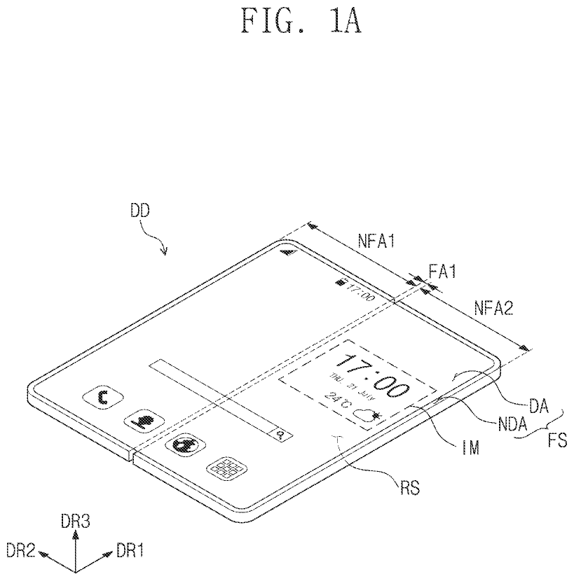

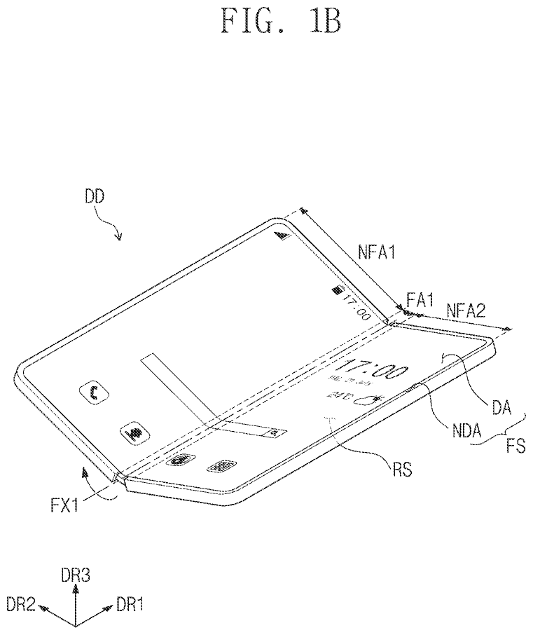

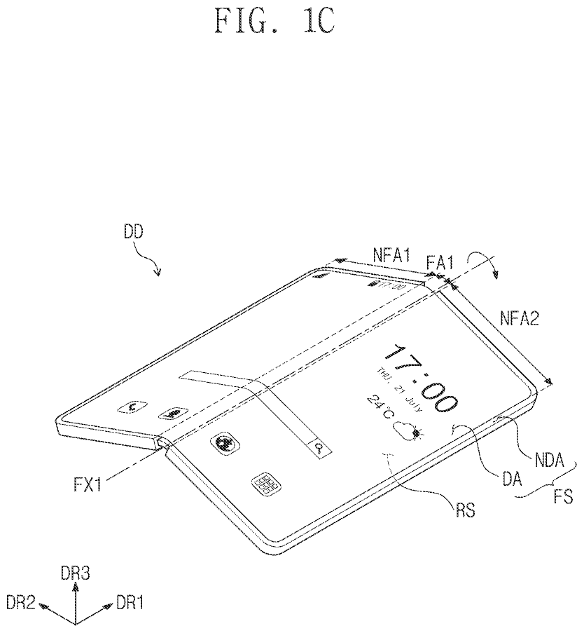

FIG. 1A is an assembled perspective view of a display device DD in an unfolded state according to an embodiment of the present disclosure, FIG. 1B is an assembled perspective view of the display device DD being inwardly folded according to an embodiment of the present disclosure, and FIG. 1C is an assembled perspective view of the display device DD being outwardly folded according to an embodiment of the present disclosure.

The display device DD may be a device that is activated in response to an electrical signal. As an example, the display device DD may be a mobile phone, a tablet computer, a car navigation unit, a game unit, or a wearable unit, however, it should not be limited thereto or thereby. In the present embodiment, the mobile phone will be described as the display device DD.

Meanwhile, in FIG. 1A and subsequent figures, a first direction DR1, a second direction DR2, and a third direction DR3 are shown, and directions indicated by the first, second, and third directions DR1, DR2, and DR3 may be relative to each other.

Referring to FIGS. 1A to 1C, the display device DD may include a first display surface FS defined by the first direction DR1 and the second direction DR2 intersecting the first direction DR1. The display device DD may provide an image IM to a user through the first display surface FS. The display device DD may display the image IM through the first display surface FS toward the third direction DR3, which is substantially parallel to each of the first direction DR1 and the second direction DR2. In the present embodiment, front (or upper) and rear (or lower) surfaces of each member of the display device DD may be defined with respect to a direction in which the image IM is displayed. The front and rear surfaces may be opposite to each other in the third direction DR3, and a normal line direction of each of the front and rear surfaces may be substantially parallel to the third direction DR3.

The display device DD may include the first display surface FS and a second display surface RS. The first display surface FS may include a display area DA and a non-display area NDA. An electronic module area (not shown) may be included in the display area DA. The second display surface RS may be opposite to at least a portion of the first display surface FS. That is, the second display surface RS may be defined as a portion of a rear surface of the display device DD.

The display device DD may sense an external input applied thereto from the outside. The external input may include various forms of inputs provided from the outside of the display device DD. For example, the external inputs may include a proximity input (e.g., hovering) applied when approaching close to or adjacent to the display device DD at a predetermined distance as well as a touch input by a part of a user's body (e.g., a user's hand). In addition, the external inputs may be provided in the form of force, pressure, temperature, light, etc.

The display device DD may include a folding area FA1 and non-folding areas NFA1 and NFA2. The display device DD may include a first non-folding area NFA1 and a second non-folding area NFA2 spaced apart from the first non-folding area NFA1 with the folding area FA1 interposed therebetween. Meanwhile, FIGS. 1A to 1C show a structure in which the display device DD includes one folding area FA1 as a representative example, however, the display device DD should not be limited thereto or thereby. According to an embodiment, the display device DD may include a plurality of folding areas defined therein.

Referring to FIG. 1B, the display device DD may be folded about a first folding axis FX1. The first folding axis FX1 may be an imaginary axis extending in the first direction DR1 to be substantially parallel to a direction in which a long side of the display device DD extends. The first folding axis FX1 may extend in the first direction DR1 on the first display surface FS.

According to an embodiment, the non-folding areas NFA1 and NFA2 may be disposed adjacent to each other with the folding area FA1 interposed therebetween. For example, the first non-folding area NFA1 may be disposed adjacent to one side of the folding area FA1 in the second direction DR2, and the second non-folding area NFA2 may be disposed adjacent to the other side of the folding area FA1 in the second direction DR2.

The display device DD may be folded about the first folding axis FX1 to be in an inwardly folded (in-folding) state where one area of the first display surface FS, which overlaps the first non-folding area NFA1, faces the other area of the first display surface FS, which overlaps the second non-folding area NFA2. Meanwhile, the second display surface RS may be viewed by the user when the display device DD is in the inwardly folded state. The second display surface RS may further include the electronic module area in which an electronic module including various components is disposed.

Referring to FIG. 1C, the display device DD may be folded about the first folding axis FX1 to be in an outwardly folded (out-folding) state where one area of the second display surface RS, which overlaps the first non-folding area NFA1, faces the other area of the second display surface RS, which overlaps the second non-folding area NFA2. However, the display device DD should not be limited thereto or thereby. According to an embodiment, the display device DD may be folded about a plurality of folding axes such that a portion of the first display surface FS and a portion of the second display surface RS face each other, and the number of the folding axes and the number of non-folding areas should not be particularly limited.

The display device DD may include various electronic modules. For example, the electronic module may include at least one of a camera, a speaker, an optical sensor, and a thermal sensor. The electronic module may sense an external object through the first display surface FS or the second display surface RS, or the electronic module may provide a sound signal, such as a voice, to the outside through the first display surface FS or the second display surface RS. In addition, the electronic module may include a plurality of components, however, it should not be limited to a particular embodiment.

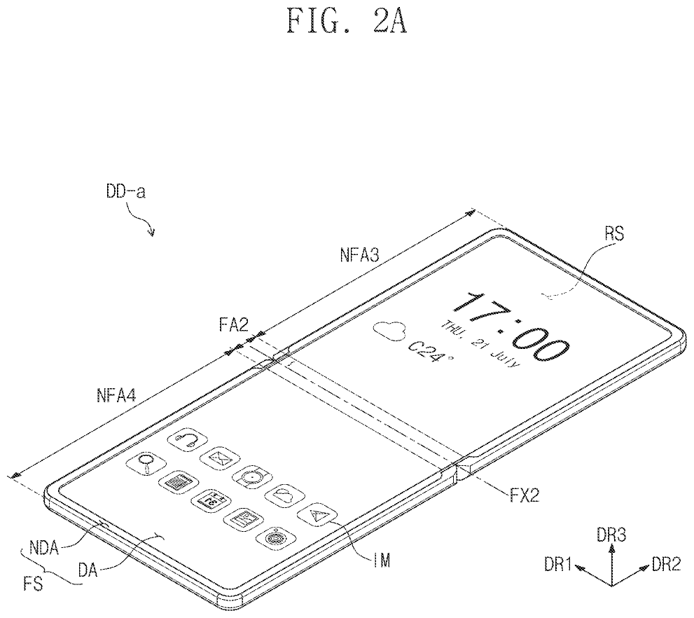

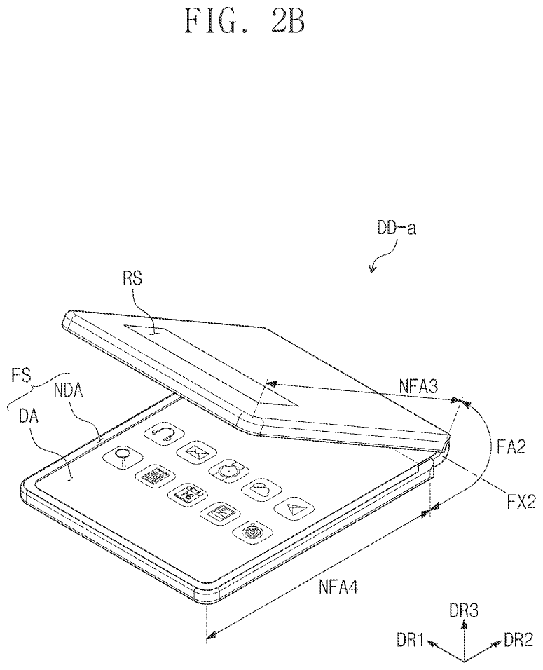

FIG. 2A is an assembled perspective view of a display device DD-a in an unfolded state according to an embodiment of the present disclosure, and FIG. 2B is an assembled perspective view of the display device DD-a being inwardly folded according to an embodiment of the present disclosure.

The display device DD-a may be folded about a second folding axis FX2 extending in a direction substantially parallel to the first direction DR1. In FIG. 2B, the second folding axis FX2 extends substantially parallel to a direction in which a short side of the display device DD-a extends, however, the present disclosure should not be limited thereto or thereby.

According to an embodiment, the display device DD-a may include at least one folding area FA2 and non-folding areas NFA3 and NFA4 defined adjacent to the folding area FA2. The non-folding areas NFA3 and NFA4 may be spaced apart from each other with the folding area FA2 interposed therebetween.

Referring to FIG. 2B, the display device DD-a may be inwardly folded (in-folding) such that a third non-folding area NFA3 and a fourth non-folding area NFA4 face each other and a display surface FS is not exposed to the outside. In addition, different from FIG. 2B, the display device DD-a may be outwardly folded (out-folding) such that the display surface FS is exposed to the outside. According to an embodiment, the display device DD-a may include a first display surface FS and a second display surface RS, and the first display surface FS may include a display area DA and a non-display area NDA. In addition, the display device DD-a may further include various electronic modules.

The display devices DD and DD-a described with reference to FIGS. 1A to 1C, 2A, and 2B may be configured to repeat the unfolding operation and the in-folding operation or to repeat the unfolding operation and the out-folding operation, however, the present disclosure should not be limited thereto or thereby. According to an embodiment, the display devices ED and ED-a may be selectively operated in any one of the unfolding operation, the in-folding operation, and the out-folding operation. Although not shown in figures, according to an embodiment, a display device may be a flexible display device including a plurality of folding areas or at least a bendable or rollable portion.

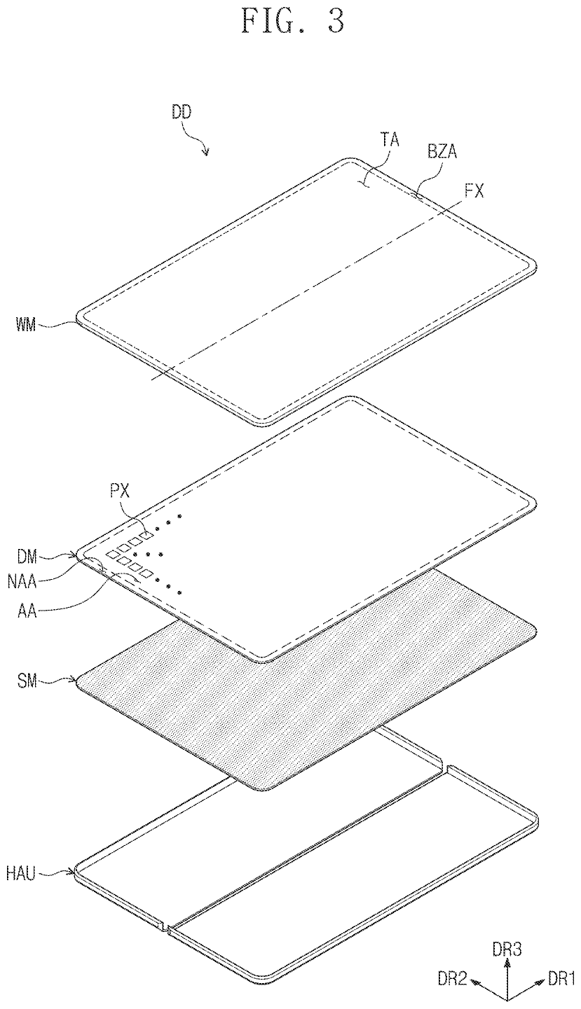

FIG. 3 is an exploded perspective view of the display device DD according to an embodiment of the present disclosure. In detail, FIG. 3 is an exploded perspective view of the display device DD of FIG. 1A.

Referring to FIG. 3, the display device DD may include a display module DM, a window WM disposed on the display module DM, and a support module SM disposed under the display module DM. The display module may be referred to as a display panel.

The window WM or the support module SM may be disposed on at least one of upper and lower portions of the display module DM. FIG. 3 shows the structure in which the window WM is disposed on the display module DM and the support module DM is disposed under the display module DM.

In addition, the display device DD may further include an electronic module (not shown) disposed under the display module DM. As an example, the electronic module (not shown) may include a camera module.

Although not shown in figures, the display device DD may further include an adhesive member or a polarizing film or both disposed between the display module DM and the window WM. In addition, although not shown in figures, the display device DD may further include lower functional layers disposed between the display module DM and the support module SM.

The display device DD may further include a housing HAU accommodating the display module DM the lower functional layers. The window WM and the housing HAU may be coupled to each other to provide an exterior of the display device DD. The housing HAU may include a material with a relatively high rigidity. As an example, the housing HAU may include a plurality of frames or plates formed of a glass, plastic, or metal material. The display module DM may be accommodated in an accommodation space of the housing HAU and may be protected from external impacts. Although not shown in figures, the housing HAU may further include a hinge structure to facilitate the folding or bending of the display device DD.

The display module DM may display the image IM in response to the electrical signal and may transmit/receive information about the external input. The display module DM may include a display panel and a sensor layer disposed on the display panel.

The display module DM may include an active area AA and a peripheral area NAA. The active area AA may provide the image IM (refer to FIG. 1A). Pixels PX may be arranged in the active area AA. The peripheral area NAA may be disposed adjacent to the active area AA. The peripheral area NAA may surround the active area AA. A driving circuit or a driving line may be arranged in the peripheral area NAA to drive the active area AA.

The display module DM may include the pixels PX. The pixels PX may display lights in response to the electrical signal. The lights displayed by the pixels PX may be implemented as the image IM. Each of the pixels PX may include a display element. As an example, the display element may be an organic light emitting element, an inorganic light emitting element, an organic-inorganic light emitting element, a micro-LED, a nano-LED, a quantum dot light emitting element, an electrophoretic element, or an electrowetting element.

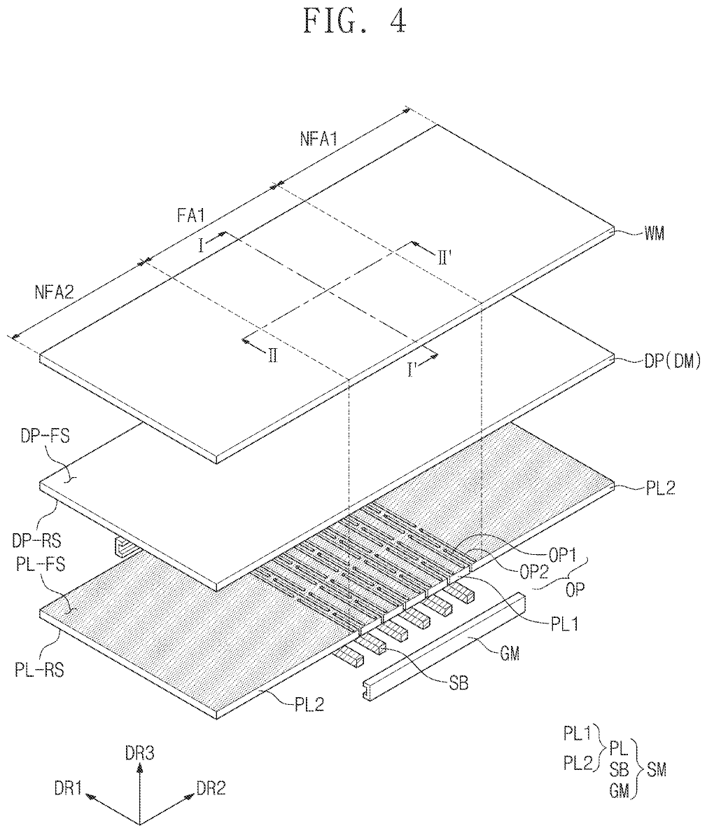

The display module DM may include a display panel DP (refer to FIG. 4) including a plurality of pixels PX, a panel protective layer, and an impact absorbing layer. In addition, the display module DM may further include functional layers, such as a barrier layer, and an adhesive layer may be disposed between the functional layers or may be omitted to allow the functional layers to be in contact with each other.

The display module DM may include a folding area FA1 (refer to FIG. 4) and non-folding areas NFA1 and NFA2 (refer to FIG. 4) extending from the folding area FA1 (refer to FIG. 4) in the second direction DR2. The folding area FA1 (refer to FIG. 4) may be supported by a first plate PL1 of the support module SM, which is described later, and the non-folding areas NFA1 and NFA2 (refer to FIG. 4) may be supported by a second plate PL2 of the support module SM, which is described later.

Referring to FIG. 3, the window WM may entirely cover an upper surface of the display module DM. The window WM may have a shape corresponding to a shape of the display module DM. The window WM may have a flexibility, and thus, the shape of the window WM may be changed according to the folding or bending of the display device DD. The window WM may protect the display module DM from external impacts.

The window WM may include a transmissive area TA and a bezel area BZA. The transmissive area TA may overlap at least a portion of the active area AA of the display module DM. The transmissive area TA may be an optically transparent area. For example, the transmissive area TA may have a transmittance of about 90% or more with respect to a visible light. The image IM (refer to FIG. 1A) may be provided to a user through the transmissive area TA, and the user may receive information from the image IM (refer to FIG. 1A).

The bezel area BZA may have a light transmittance relatively lower than that of the transmissive area TA. The bezel area BZA may define a shape of the transmissive area TA. The bezel area BZA may have a predetermined color. The bezel area BZA may cover the peripheral area NAA of the display module DM to prevent the peripheral area NAA from being viewed from the outside, however, this is merely an example. According to an embodiment, the bezel area BZA may be omitted from the window WM.

During the repeat of the folding and unfolding operations, a stress may be applied to the display module DM. When the stress is repeatedly applied to the display module DM, a crease, e.g., curves, may occur in a portion adjacent to an area overlapping the folding axis FX of the folding area of the display module DM. The crease may cause a deterioration in display reliability of the display panel.

The support module SM may be disposed under the display module DM and may support the display module DM. The support module SM may support the display module DM that is folded at a predetermined curvature. The support module SM may relieve the stress applied to the display module DM during the folding and unfolding operations. When the stress applied to the display module DM is relieved, the crease may be prevented from occurring in components of the display module DM, for example, the display panel DP (refer to FIG. 4).

In addition, the support module SM may prevent the display module DM from being excessively folded upward or downward and may prevent impacts from being applied to the display module DM in the housing HAU.

The support module SM may have the same width as that of the display module DM. The support module SM may have higher rigidity than that of the display module DM. A portion of the support module SM may be coupled with the housing HAU, and the other portion of the support module SM may be coupled with the display module DM.

FIG. 4 is an exploded perspective view of the display device according to an embodiment of the present disclosure. In detail, FIG. 4 is an exploded perspective view of the display device in which a support plate PL, a support bar SB, and guide members GM among components of the support module SM of FIG. 3 are embodied in detail.

Referring to FIG. 4, the support plate PL may be disposed under the display panel DP and may support the display panel DP. The support plate PL may be disposed on a rear surface DP-RS of the display panel DP, and a front surface PL-FS of the support plate PL may face the rear surface DP-RS of the display panel DP. The support plate PL may have substantially the same width as that of the display panel DP. The support plate PL may have higher rigidity than that of the display panel DP.

The support plate PL may support the display panel DP folded at the predetermined curvature. The support plate PL may relieve the stress applied to the display panel DP during the folding and unfolding operations.

The support plate PL may include a first plate PL1 and a second plate PL2. The first plate PL1 may overlap the folding area FA1, and the second plate PL2 may overlap the non-folding areas NFA1 and NFA2. The second plate PL2 may extend from the first plate PL1 to the second direction DR2.

FIG. 4 shows the structure in which the first plate PL1 is provided integrally with the second plate PL2, however, the present disclosure should not be limited thereto or thereby. According to an embodiment, the first plate PL1 and the first plate PL1 may be spaced apart from each other by a predetermine distance, but they should not be particularly limited.

The support plate PL may include a non-metallic material. As an example, the support plate PL may include a reinforced fiber composite. The reinforced fiber composite may be a carbon fiber reinforced plastic (CFRP) or a glass fiber reinforced plastic (GFRP), however, this is merely an example. According to an embodiment, the support plate PL may include a metal material.

The support plate PL may be reduced in weight by including the reinforced fiber composite. Since the support plate PL according to the present embodiment includes the reinforced fiber composite, the support plate PL may have a similar level of modulus and strength to those of the metal support plate PL while having a lighter weight than the metal support plate PL including the metal material.

In addition, as the support plate PL includes the reinforced fiber composite, the shape of the support plate PL may be easily processed compared with the metal support plate PL. As an example, the support plate PL including the reinforced fiber composite may be easily processed by a laser process or a micro-blast process.

The first plate PL1 may be provided with a plurality of openings OP defined therethrough. The openings OP may be formed penetrating through portions of the support plate PL in the third direction DR3. As an example, the openings OP may be formed by the laser process or the micro-blast process, however, this is merely an example, and the openings OP may be formed in various ways.

As the openings OP are defined through the portions of the first plate PL1, which overlap the folding area FA1, a flexibility of the portions of the first plate PL1 overlapping the folding area FA1 may be improved. Therefore, the support plate PL may be folded about the folding area FA1.

The openings OP may include a plurality of first openings OP1 and a plurality of second openings OP2. The first openings OP1 may be arranged spaced apart from each other in the second direction DR2. The second openings OP2 may be arranged spaced apart from each other in the second direction DR2. The first openings OP1 and the second openings OP2 may partially overlap each other when viewed in a direction substantially parallel to the second direction DR2.

The first openings OP1 and the second openings OP2 may be alternately arranged with each other in the second direction DR2, and as an example, the first openings OP1 and the second openings OP2 may be arranged in a lattice form.

The support bars SB may be disposed under the support plate PL and may support the support plate PL. The support bars SB may be disposed on a rear surface PL-RS of the support plate PL. The support bar SB may support the support plate PL to allow the support plate PL to relieve the stress applied to the display panel DP during the folding and unfolding operations. That is, the stress applied to the display panel DP at a constant intensity during the folding and unfolding operations may be relieved, and thus, the crease may be prevented from occurring in the display panel DP.

The support bars SB may be provided in plural. The support bars SB may be arranged spaced apart from each other at a predetermined distance in the second direction DR2. Each of the support bars SB may extend in the first direction DR1.

The support bars SB may support the first plate PL1. When viewed in the plane, the support bars SB may overlap the folding area FA1 and may not overlap the non-folding areas NFA1 and NFA2.

The support bars SB may include the same material as the support plate PL. According to an embodiment, the support bars SB may include the same material as only the first support plate PL1, however, the present disclosure should not be limited thereto or thereby.

The guide members GM may be disposed at one side and the other side, which is spaced apart from the one side in the first direction DR1, of the support bars SB. In other words, the guide members GM may be respectively disposed at first and second ends of the support beams. The guide member GM may extend in the direction to which the support bars SB are arranged (i.e. the second direction DR2). However, the direction in which the guide member GM extends should not be particularly limited to the second direction DR2.

First and second ends of each of the support bars SB may be respectively accommodated in first and second guide members GM. The guide members GM may prevent the support bars SB from being separated from predetermined positions during the folding and unfolding operations. Accordingly, the state in which the support bars SB supports the support plate PL may be maintained during the folding and unfolding operations. The guide members GM may be in contact with at least one surface of each of the support bars SB, however, it should not be limited thereto or thereby. According to an embodiment, the guide member GM may be in contact with two or more surfaces of each of the support bars SB.

The display panel DP, the support bars SB, and the guide member GM may be accommodated in the housing HAU. The guide member GM may be coupled with the housing HAU (refer to FIG. 3), however, the present disclosure should not be limited thereto or thereby.

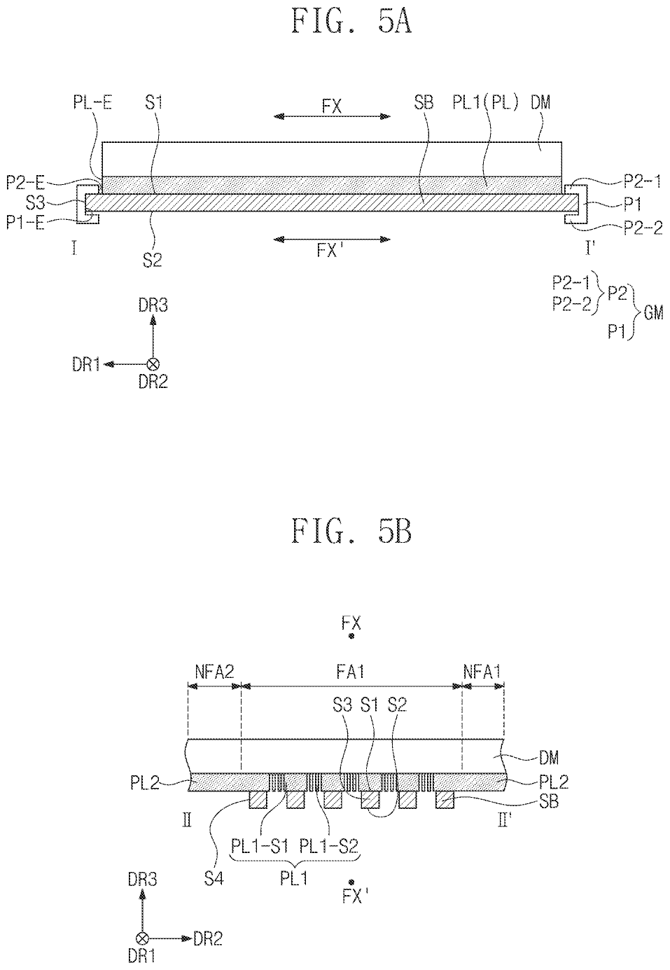

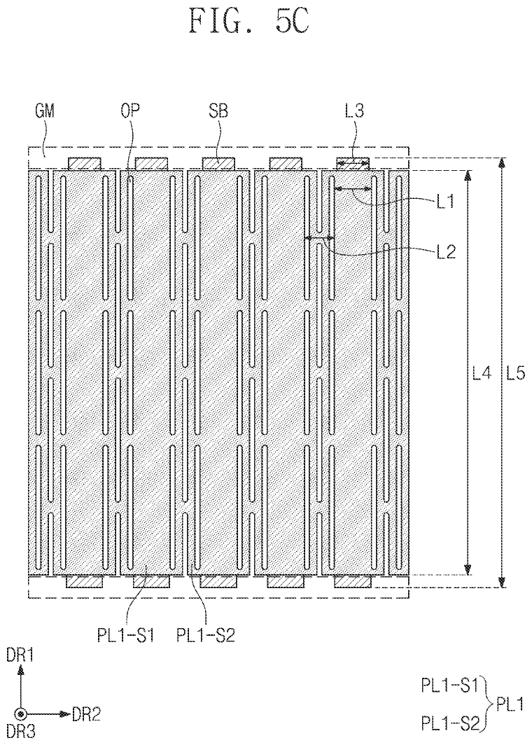

FIG. 5A is a cross-sectional view of a portion of the display device according to an embodiment of the present disclosure, FIG. 5B is a cross-sectional view of a portion of the display device according to an embodiment of the present disclosure, and FIG. 5C is a plan view of a portion of the display device according to an embodiment of the present disclosure. In detail, FIG. 5A is a cross-sectional view of the portion of the display device taken along a line I-I′ of FIG. 4, and FIG. 5B is a cross-sectional view of the portion of the display device taken along a line II-II′ of FIG. 4.

Referring to FIGS. 5A and 5B, the first plate PL1 of the support plate PL may be disposed on the support bar SB, and the display module DM may be disposed on the support plate PL. In addition, the guide member GM may support the support bar SB.

Each of the support bars SB may include a first surface S1 facing the display module DM, a second surface S2 opposite to the first surface S1, third surfaces S3 connecting the first surface S1 and the second surface S2 with of the third surfaces S3 at the first end of a guide member GM and another of the third surfaces S3 at the second end of the guide member GM, and fourth surfaces S4 connecting the first surface S1 and the second surface S2. The third and fourth surfaces S3 and S4 may be provided in plural, the third surfaces S3 may be opposite to each other in the first direction DR1, and the fourth surfaces S4 may be opposite to each other in the second direction DR2. In detail, the third surfaces S3 may be surfaces of the support bars SB, which face the guide member GM, and the fourth surfaces may be surfaces of the support bars SB, which face each other.

The guide member GM may include a first portion P1 and a second portion P2. An inner side surface of the first portion P1 may face the third surface S3 of the support bar SB. The inner side surface of the first portion P1 may be in contact with the third surface S3 of the support bar SB. The first portion P1 may not overlap the support bar SB when viewed in the plane.

The second portion P2 may extend from the first portion P1 to the first direction DR1. The second portion P2 may be in contact with the support bar SB. The second portion P2 may overlap the support bar SB when viewed in the plane.

An edge P2-E of the second portion P2 may be spaced apart from an edge PL-E of the first plate PL1. The second portion P2 may not overlap the first plate PL1 when viewed in the plane. Since the second portion P2 does not overlap the first plate PL1, the support plate PL or the support bar SB may easily move during the folding and unfolding operations.

FIGS. 5A to 5C show the structure in which a first support portion P2-1 and a second support portion P2-2, which are described later, do not overlap the first plate PL1, however, the present disclosure should not be limited thereto or thereby. According to an embodiment, only the first support portion P2-1 may not overlap the first plate PL1, and the second support portion P2-2 may overlap the first plate PL1.

The second portion P2 may include the first support portion P2-1 and the second support portion P2-2. The first support portion P2-1 and the second support portion P2-2 may respectively extend from one side and the other side of the first portion P1 to the first direction DR1. The first support portion P2-1 may be in contact with the first surface S1 of the support bar SB. FIGS. 5A to 5C show the structure in which the first support portion P2-1 is in contact with the first surface S1 of the support bar SB, however, the present disclosure should not be limited thereto or thereby. According to an embodiment, the second surface S2 of the support bar SB may be in contact with the second support portion P2-2 according to the movement of the support bar SB.

As shown in FIG. 5A, the first portion P1 and the second portion P2 of the guide member GM may have a quadrangular shape, however, this is merely an example. According to an embodiment, the first portion P1 and the second portion P2 may have an oval shape.

A folding axis may be provided in plural, and the folding axes FX and FX′ may correspond to the folding axis FX of the display device inwardly folded and a folding axis FX′ of the display device outwardly folded, respectively. In detail, the first folding axis FX defined above the support bar SB may correspond to the folding axis FX1 in the in-folding state of the display device shown in FIG. 1B, and the second folding axis FX′ defined under the support bar SB may correspond to the folding axis FX1 in the out-folding state of the display device shown in FIG. 1C.

As an example, when the stress is applied downward to the display module DM, e.g., a portion of the display module DM adjacent to the first folding axis FX in the plane, during the in-folding and unfolding states of the display device, the first plate PL1 may support the display module DM upward and may relieve the stress concentrated on the portion of the display module DM. In addition, the support bars SB disposed under the first plate PL1 may support the first plate PL1 upward, and the guide member GM may support the support bars SB upward. In detail, the second support portion P2-2 of the guide member GM may support the support bars SB upward. Since the guide member GM supports the support bars SB upward, the support bars SB may be prevented from being spaced apart from the first plate PL1, and thus, the first plate PL1 may be supported by the support bars SB. Accordingly, the stress applied to the display module DM at a constant intensity during the in-folding and unfolding states of the display device may be relieved, and thus, the curves, e.g., creases, may be prevented from occurring in the display module DM, e.g., in the display panel.

In addition, as an example, when the stress is applied upward to the display module DM, e.g., a portion of the display module DM adjacent to the second folding axis FX′ in the plane, during the out-folding and unfolding operations of the display device, the first plate PL1 may support the display module DM downward and may relieve the stress concentrated on the portion of the display module DM. In addition, the support bars SB disposed under the first plate PL1 may support the first plate PL1 downward, and the guide member GM may support the support bars SB downward. In detail, the first support portion P2-1 of the guide member GM may support the support bars SB downward. Since the guide member GM supports the support bars SB downward, the support bars SB may be prevented from being spaced apart from the first plate PL1, and thus, the first plate PL1 may be supported by the support bars SB. Accordingly, the stress applied to the display module DM at a constant intensity during the out-folding and unfolding operations of the display device may be relieved, and thus, the curves, e.g., creases, may be prevented from occurring in the display module DM, e.g., in the display panel.

For the convenience of explanation, components of the guide member GM are omitted in FIG. 5B.

Referring to FIG. 5B, the first plate PL1 may include a first support portion PL1-S1 and a second support portion PL1-S2. Each of the first support portion PL1-S1 and the second support portion PL1-S2 may be provided in plural. The first support portions PL1-S1 and the second support portions PL1-S2 may be arranged in the second direction DR2.

According to an embodiment, the first support portions PL1-S1 may be alternately arranged with the second support portions PL1-S2, however, they should not be limited thereto or thereby.

Referring to FIGS. 5A to 5C, the first support portion PL1-S1 of the first plate PL1 is connected to the second plate PL2, however, the present disclosure should not be limited thereto or thereby. According to an embodiment, the second support portion PL1-S2 of the first plate PL1 may be connected to the second plate PL2, but it should not be limited thereto or thereby.

The support bars SB may be disposed under the first support portions PL1-S1, respectively. As shown in FIG. 5B, the support bars SB may overlap the first support portions PL1-S1 in the folding area FA1.

For the convenience of explanation, components of the guide member GM, which overlap the support bar SB, are the FIG. 5C, are shown in dotted lines.

Referring to FIG. 5C, the support bar SB may support the first support portion PL1-S1 as described above. The second support portion PL1-S2 may be provided with a plurality of openings OP defined therethrough, and the openings OP may be arranged in the lattice form.

The first support portion PL1-S1 may have a first width L1 in the second direction DR2, and the second support portion PL1-S2 may have a second width L2 in the second direction DR2. The first width L1 in the second direction DR2 of the first support portion PL1-S1 may be equal to or greater than the second width L2 in the second direction DR2 of the second support portion PL1-S2.

As an example, the first width L1 of the first support portion PL1-S1 may be equal to or greater than the second width L2 of the second support portion PL1-S2 and may be equal to or smaller than four times of the second width L2 of the second support portion PL1-S2. According to an embodiment, the first width L1 of the first support portion PL1-S1 may be equal to or greater than three times of the second width L2 of the second support portion PL1-S2 and may be equal to or smaller than four times of the second width L2 of the second support portion PL1-S2. In a case where the second width L2 of the second support portion PL1-S2 is about 0.2 mm, the first width L1 of the first support portion PL1-S1 may be equal to or greater than about 0.6 mm and equal to or smaller than about 0.8 mm.

The first width L1 in the second direction DR2 of the first support portion PL1-S1 may be equal to or greater than a third width L3 in the second direction DR2 of the support bar SB. When the first width L1 in the second direction DR2 of the first support portion PL1-S1 is greater than the second width L2 in the second direction DR2 of the support bar SB, a reliability in support of the support bar SB with respect to the first support portion PL1-S1 may be improved. In addition, the support bar SB may be prevented from being separated from the first support portion PL1-S1 and from supporting the second support portion PL1-S2.

A length L4 in the first direction DR1 of the first plate PL1 may be equal to or smaller than a length L5 in the first direction DR1 of the support bar SB. That is, a portion of each of the support bars SB may overlap the first plate PL1 when viewed in the plane, and the other portion of each of the support bars SB may not overlap the first plate PL1 when viewed in the plane.

The first plate PL1 may not overlap the guide member GM when viewed in the plane, however, this is merely an example. According to an embodiment, the second support portion P2-2 (refer to FIG. 5A) of the guide member GM may overlap the first plate PL1, but the present disclosure should not be particularly limited.

FIG. 5D is a cross-sectional view of a portion of a display device. In detail, FIG. 5D shows the display device different from the display device shown in FIG. 5A. In FIG. 5D, the same reference numerals denote the same elements in FIG. 5A, and thus, detailed descriptions of the same elements will be omitted.

Referring to FIG. 5D, a third surface S3 of a support bar SB may be spaced apart from an inner side surface of a first portion P1 of a guide member GM by a predetermined distance. That is, the guide member GM may be in contact with one surface of each of the support bars SB. FIG. 5D shows the structure in which a first support portion P2-1 of the support bar SB is in contact with a first surface S1 of the guide member GM, however, the present disclosure should not be limited thereto or thereby. According to an embodiment, a second support portion P2-2 of the support bar SB may be in contact with a second surface S2 of the guide member GM.

An inner side surface of the first portion P1 of the guide member GM may be spaced apart from a third surface S3 of the support bar SB, and thus, the support bars SB may easily move during the folding and unfolding operation of the display device. As a result, a reliability in support of the support plate PL may be improved by the support bars SB.

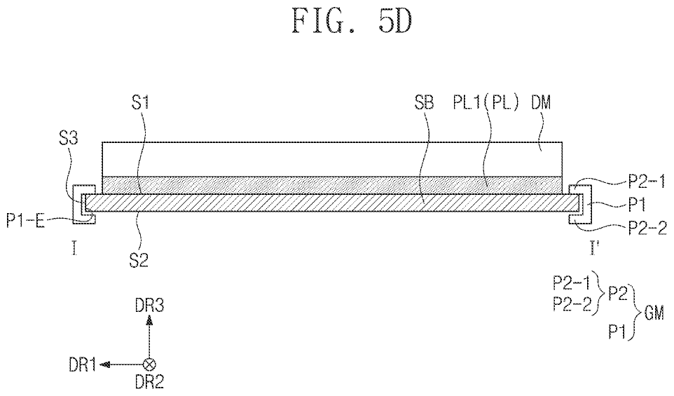

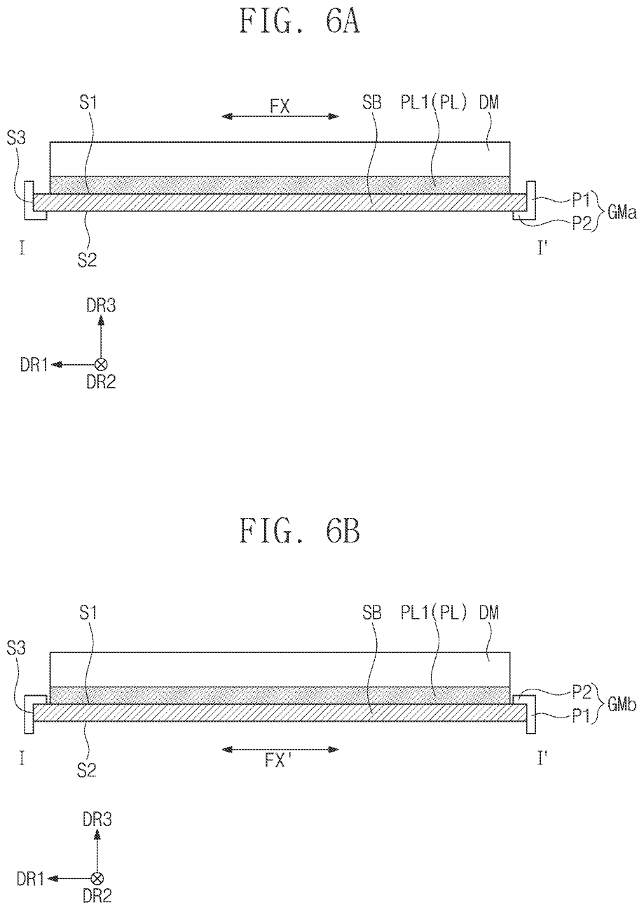

FIGS. 6A and 6B are cross-sectional views of display devices according to embodiments of the present disclosure. In detail, FIGS. 6A and 6B show the display devices different from the display device shown in FIG. 5A. In FIGS. 6A and 6B, the same reference numerals denote the same elements in FIG. 5A, and thus, detailed descriptions of the same elements will be omitted.

In FIG. 6A, a folding axis FX of the display device may be defined above a support bar SB. In detail, the folding axis FX may correspond to the folding axis FX1 of the display device inwardly folded as shown in FIG. 1B.

A second portion P2 of a guide member GMa may be in contact with a second surface S2 of each of the support bars SB. When the display device is inwardly folded, a first plate PL1 coupled with a display module DM may support the display module DM upward against a stress applied to the display module DM. That is, the stress concentrated on a lower portion of the display module DM may be relieved. In addition, the support bars SB disposed under the first plate PL1 and coupled with the first plate PL1 may support the first plate PL1 upward. Accordingly, the stress concentrated on the lower portion of the display module DM may be relieved. The guide member GM may support the support bars SB upward when the support bars SB support the first plate PL1 upward, and thus, the stress applied to the display module DM at a constant intensity during in-folding and unfolding operations may be relieved. As a result, creases may be prevented from occurring in the display module DM.

In FIG. 6B, a folding axis FX′ of the display device may be defined under a support bar SB. In detail, the folding axis FX′ may correspond to the folding axis FX1 of the display device outwardly folded as shown in FIG. 1C.

A second portion P2 of the guide member GMb may be in contact with a first surface S1 of each of the support bars SB. A first plate PL1 coupled with a display module DM may support the display module DM downward against the stress applied to an upper portion of the display module DM during an out-folding operation. That is, the stress concentrated on the upper portion of the display module DM may be relieved. In addition, the support bars SB disposed under the first plate PL1 and coupled with the first plate PL1 may support the first plate PL1 downward and may support the display module DM downward together with the first plate PL1. Accordingly, the stress concentrated on the upper portion of the display module DM may be relieved. The guide member GM may support the support bars SB downward when the support bars SB support the first plate PL1 downward, and thus, the stress applied to the display module DM at a constant intensity during out-folding and unfolding operations may be relieved. As a result, creases may be prevented from occurring in the display module DM.

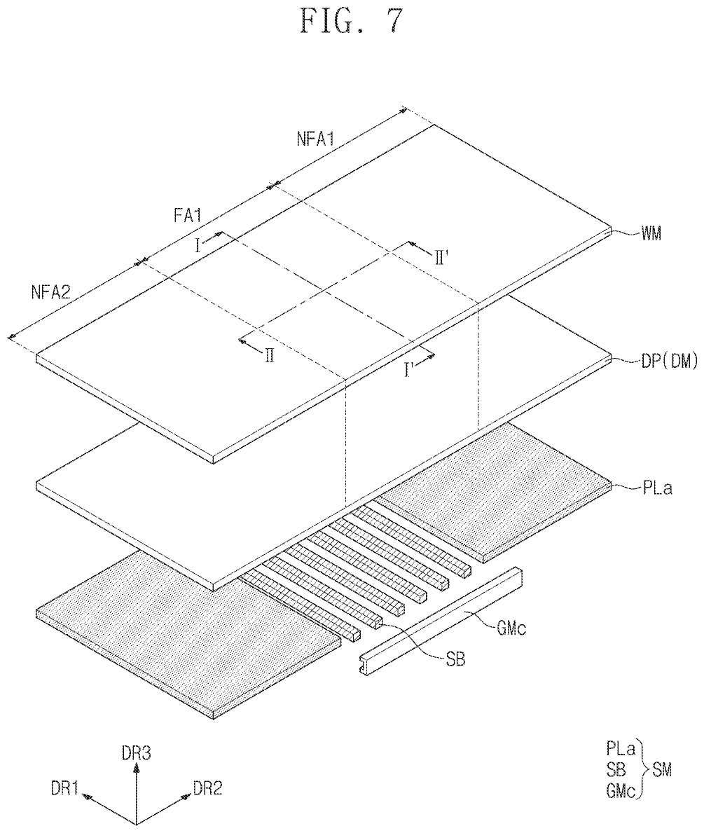

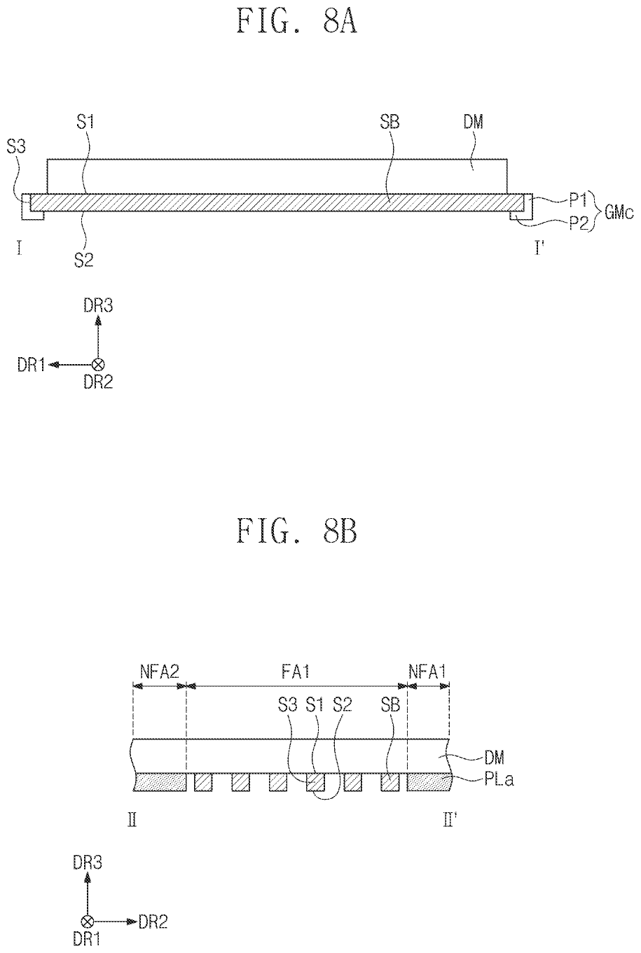

FIG. 7 is an exploded perspective view of a display device according to an embodiment of the present disclosure, and FIGS. 8A and 8B are cross-sectional views of a portion of the display device according to embodiments of the present disclosure. In detail, FIG. 7 is an exploded perspective view of the display device different from the display device shown in FIG. 4, FIG. 8A is a cross-sectional view of the portion of the display device taken along a line I-I′ of FIG. 7, and FIG. 8B is a cross-sectional view of the portion of the display device taken along a line II-II′ of FIG. 7.

In FIGS. 7, 8A and 8B, the same reference numerals denote the same elements in FIGS. 4 and 5A to 5C, and thus, detailed descriptions of the same elements will be omitted.

Referring to FIG. 7, a support plate PLa may support non-folding areas NFA1 and NFA2 of a display panel DP. The support plate PLa may overlap the non-folding areas NFA1 and NFA2 of the display panel DP. In addition, the support plate PLa may not overlap a folding area FA1.

Support bars SB may support the folding area FA1 of the display panel DP. The support bars SB may be in contact with the display panel DP. The support plate PLa may be divided into plural portions, and the support bars SB may be disposed between the portions of the support plate PLa.

A guide member GMc may be disposed at one side and the other side spaced apart from the one side in the first direction DR1 of the support bars SB. Each of the support bars SB may be accommodated in the guide member GMc. When viewed in the first direction DR1, the guide member GMc may not overlap the support plate PLa, however, the present disclosure should not be limited thereto or thereby. According to an embodiment, the guide member GMc may partially overlap the support plate PLa.

Referring to FIGS. 8A and 8B, the support bars SB may support the display module DM in the folding area FA1. A first surface S1 of each of the support bars SB may be in contact with the display module DM. The guide member GM may support the support bars SB in the folding area FA1. The support plate PLa may support the display module DM in the non-folding areas NFA1 and NFA2.

FIG. 8A shows the structure in which the guide member GMc supports a second surface S2 and a third surface S3 of the support bars SB, however, the present disclosure should not be limited thereto or thereby. According to an embodiment, the guide member GMc may support the first surface S1 and the third surface S3 of the support bars SB, but it should not be limited thereto or thereby.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to embodiments described herein, and the scope of the present inventive concept shall be determined according to the attached claims.

What is claimed is:

1. A display device comprising:
a display panel comprising a folding area and a non-folding area adjacent to the folding area;
a plurality of support bars arranged spaced apart from each other at a predetermined distance along a one direction in the folding area, extending in a cross direction intersecting the one direction, and comprising a first surface facing the display panel and a second surface opposite to the first surface; and
first and second guide members respectively disposed at a first end and a second end of each of the support bars and spaced apart in the cross direction, wherein each of the first and second guide members supports at least one of the first surface and the second surface of each of the support bars.

2. The display device of claim 1, wherein each of the first and second guide members comprises:
a first portion that does not overlap the support bars when viewed in a plane; and
a second portion bent from the first portion and overlapping the support bars when viewed in the plane.

3. The display device of claim 2, wherein the second portion comprises:
a first support portion extending in the cross direction and facing the first surface; and
a second support portion facing the second surface.

4. The display device of claim 3, wherein the first support portion does not overlap the display panel when viewed in the plane.

5. The display device of claim 1, further comprising a first plate disposed in the display panel and overlapping the folding area, wherein the first plate comprises:
a plurality of first support portions each having a first width in the one direction and arranged in the one direction; and
a plurality of second support portions each having a second width equal to or smaller than the first width in the one direction and disposed between the first support portions, and the support bars overlap the first support portions, respectively, when viewed in a plane.

6. The display device of claim 5, further comprising a second plate that is disposed in the display panel, overlaps the non-folding area, and does not overlap the folding area.

7. The display device of claim 5, wherein each of the second support portions is provided with a plurality of openings defined therethrough, and the openings are arranged in a lattice form when viewed in the plane.

8. The display device of claim 5, wherein a first length in the cross direction of the first plate is smaller than a second length in the cross direction of the support bars.

9. The display device of claim 1, wherein the first and second guide members extends in the one direction.

10. The display device of claim 1, wherein each of the support bars comprises a plurality of third surfaces each connecting the first surface and the second surface and facing each other in the cross direction, and the first and second guide members are in contact with the third surfaces of the support bars.

11. A display device comprising:
a display panel comprising a folding area and a non-folding area adjacent to the folding area;
a support plate disposed on a rear surface of the display panel and supporting the display panel;
a plurality of support bars arranged spaced apart from each other at a predetermined distance along a one direction in the folding area, extending in a cross direction intersecting the one direction, and comprising a first surface facing the display panel and a second surface opposite to the first surface; and
first and second guide members respectively disposed at a first end and a second end of each of the support bars and spaced apart in the cross direction, wherein each of the first and second guide members supports at least one of the first surface and the second surface of each of the support bars.

12. The display device of claim 11, wherein each of the first and second guide members comprises:
a first portion that does not overlap the support bars when viewed in a plane; and
a second portion extending from the first portion to the one direction and being in contact with at least one of the first surface and the second surface.

13. The display device of claim 11, wherein the support plate comprises a first plate overlapping the folding area, the first plate comprises:
a plurality of first support portions each having a first width in the one direction and arranged in the one direction; and
a plurality of second support portions each having a second width equal to or smaller than the first width in the one direction and disposed between the first support portions, and the support bars overlap the first support portions, respectively, when viewed in a plane.

14. The display device of claim 13, wherein each of the second support portions is provided with a plurality of openings defined therethrough, and the openings are arranged in a lattice form when viewed in the plane.

15. The display device of claim 13, wherein the support plate comprises a second plate that overlaps the non-folding area and does not overlap the folding area.

16. A display device comprising:
a display panel comprising a folding area and a non-folding area adjacent to the folding area;
a first plate disposed on a rear surface of the display panel and supporting the display panel in the folding area;
a plurality of support bars arranged spaced apart from each other at a predetermined distance along a one direction in the folding area, extending in a cross direction intersecting the one direction, the plurality of support bars supporting the first plate; and
first and second guide members respectively supporting first and second ends of each the support bars, wherein the first plate comprises:
a plurality of first support portions each having a first width in the one direction and arranged in the one direction; and
a plurality of second support portions each having a second width equal to or smaller than the first width in the one direction and disposed between the first support portions, and the support bars overlap the first support portions, respectively, when viewed in a plane.

17. The display device of claim 16, wherein each of the support bars comprises:
a first surface facing the rear surface of the display panel;
a second surface opposite to the first surface; and
a plurality of third surfaces each connecting the first surface and the second surface and facing each other in the cross direction, and each of the first and second guide members supports at least one surface of the first surface and the second surface.

18. The display device of claim 17, wherein each of the first and second guide members comprises:
a first portion that does not overlap the support bars when viewed in the plane; and
a second portion extending from the first portion to the one direction and being in contact with at least one of the first surface and the second surface.

19. The display device of claim 16, wherein each of the second support portions is provided with a plurality of openings defined therethrough, and the openings are arranged in a lattice form when viewed in the plane.

20. The display device of claim 16, further comprising a second plate disposed on the rear surface of the display panel and supporting the display panel in the non-folding area.
